(19) United States
(12) Patent Application Publication
(10) Pub. No.: US 2010/0126885 A1
(43) Pub. Date: May 27, 2010

(54) SENSOR DEVICE AND METHOD OF MEASURING A SOLUTION

(76) Inventors: Hiroyuki IECHI, Miyagi (JP); Kazuhiro Kudo, Chiba (JP)

Correspondence Address: OBLON, SPIVAK, MCCLELLAND MAIER & NEUSTADT, L.L.P., 1940 DUKE STREET, ALEXANDRIA, VA, 22314, US

(21) Appl. No.: 12/615,481

(22) Filed: Nov. 10, 2009

(30) Foreign Application Priority Data
Nov. 21, 2008 (JP) 2008-298827
Dec. 24, 2008 (JP) 2008-328408

(51) Int. Cl. G01F 1/64; H01L 29/66

(52) U.S. Cl. 205/793; 257/253; 257/E29.166

(57) ABSTRACT

A sensor device includes a porous insulating layer formed of a porous insulating material; a first electrode having a first opening portion formed on a first side of the porous insulating layer; a second electrode having a second opening portion corresponding to the first opening portion formed on a second side of the porous insulating layer; an insulating layer formed on the second electrode; and a molecular recognition material disposed on internal walls of an opening in the porous insulating layer.

### BACKGROUND OF THE INVENTION

1. Field of the Invention

The present invention generally relates to sensor devices and methods of measuring solutions. Particularly, the present invention relates to a sensor device using a transistor having a porous insulating layer.

2. Description of the Related Art

Various sensors have been researched and developed, their applications ranging from industrial to medical fields. Nowadays sensors are commonly used in general households, forming an indispensable part of modern society. Sensors may be classified by what they sense, how they convert signals, and what material they are made of. In terms of how they convert signals, sensors may be roughly categorized into physical sensors, chemical sensors, and biosensors.

Biosensors are a measuring device simulating or directly taking advantage of the excellent molecular recognition capability of living bodies. Biosensors are gaining increasing attention because of their wide potential applications. A typical biosensor consists of a molecular recognition material (receptor) for receiving a certain substance and a transducer for converting a response signal into a detectable signal, such as an electric signal. The molecular recognition material may be immobilized on a membrane. Upon recognition of a target substance, the molecular detection material produces an enzyme response, breathing of a microorganism, or an immune reaction, for example. Such a response is detected as a change in current or thermal quantity, and that change is converted into an electric signal by the transducer and displayed.

The molecular recognition material may include enzymes, microorganisms, immune substances such as antibodies, genes such as DNA, and cells. The transducer may include an enzyme electrode, a hydrogen peroxide electrode, an ion electrode, a field-effect transistor, an optical fiber, a photo counter, a crystal oscillator, a surface acoustic wave device, or a thermistor, depending on the object of measurement.

FIG. 1 depicts a schematic cross section and an electric circuit diagram of an element of an insulated gate field effect transistor (IGFET) 300 as an example of a conventional bio-transistor. The IGFET 300 includes a gate insulating film 310 on a surface of which a molecular recognition material 320 is immobilized. The molecular recognition material 320 is immersed in a solution 340 together with a reference electrode 330.

The IGFET 300 controls the potential of the solution 340 using the reference electrode 330, and measures, via the reference electrode 330, the density of charge due to molecular recognition by the molecular recognition material 320 on the surface of the gate insulating film 310. Because the electron density in a channel in the silicon (Si) surface varies in response to the charge density on the surface of the gate insulating film 310, a signal due to the molecular recognition material 320 alone can be detected in principle by measuring a drain current (see “OYO BUTURI”, Vol. 74, No. 12, p. 1555-1562 (2005), for example).

It has also been proposed in recent years to apply organic material in the field of electronics to satisfy the need for more light-weight, portable, and flexible devices. Various vertical transistors employing organic material have been proposed. For example, a light-emitting element according to the related art includes a light-emitting layer made of an organic material and a transistor made of an organic material, thus forming both the light-emitting layer and its control element from organic material (see “Thin Solid Films”, Vol. 331 (1998), pp. 51-54, for example).

An example of a vertical transistor using an organic semiconductor has also been reported (see Kudo et al., “T.IEE Japan”, Vol. 118-A, No. 10, (1998) pp. 1166-1171, for example) that includes CuPc (copper phthalocyanine) sandwiched by a source electrode and a drain electrode, wherein a slit-like aluminum thin film is embedded in a CuPc layer for a gate electrode.

There has also been a report of the performance of a light-emitting element having an organic transistor, specifically a vertical organic light-emitting transistor in which α-NPD(bis-1-N naphthyl N phenylbenzidine) is used as a hole transport material, Alq₃ (8-hydroxyquinolate aluminum complex compound) is used as a light-emitting material, and a gate electrode is disposed in an α-NPD layer (see Ikegami et al., “Technical Report of IEICE”, OME2000-20, pp. 47-51, for example).

Hereafter, the concept of a three-phase zone in an anode enzyme electrode reaction system according to an energy conversion technology is described with reference to FIG. 2. The three-phase zone is formed by an enzyme catalyst, an ion conductor, and fuel. As illustrated in FIG. 2, the resistance involved in proton conduction and the resistance involved in electron conduction are due to polarization in the three-phase zone. This concept provides a guidance concerning the designing of a bio-transistor. Specifically, it can be seen that, because proton production takes place in the three-phase zone at the anode pole, it is important to decrease the resistance involved in electron conduction for energy conversion.

This suggests that, in the context of electric conduction of a bio-transistor, such as the IGFET 300 depicted in FIG. 1, the resistance involved in charge conduction can be reduced by locating the three-phase zone formed by the molecular recognition material 320 on the surface of the gate insulating film 310, the ion conductor, and one electrode closer to another electrode. It also suggests that a signal can be acquired at high speed by reducing the resistance involved in charge conduction. However, because the IGFET 300 depicted in FIG. 1 is based on a horizontal field-effect transistor structure, there is a limit as to how closely the three-phase zone and the electrode position can be positioned to each other.

In contrast to horizontal type field-effect transistors, such as MOS (Metal Oxide Semiconductor) transistors, in which current flows horizontally with respect to the conducting layer, current flows vertically with respect to the conducting layer in a vertical field-effect transistor. Thus, in a vertical field-effect transistor, the channel length, i.e., the length of a current path of the transistor, can be reduced to approximately the thickness of the conducting layer. In addition, the drain current can be increased, thus enabling the transistor to operate at high speed. The vertical field-effect transistor also has a simple element structure, allowing the transistor to have a reduced element size.

Such features of the vertical transistor make a vertical organic transistor far more suitable and advantageous when used as a control element (also referred to as a switching element) for a light-emitting layer, such as an organic EL layer, than a horizontal organic transistor because a display device using an organic EL layer requires high-speed response. Therefore, research and development of a flexible sheet display using organic vertical transistors as control elements are currently being actively conducted.

However, in order to apply this vertical transistor technology to bio-transistors and reduce the resistance involved in charge conduction by bringing the position of the three-phase zone formed by the molecular recognition material on the gate insulating film surface, the ion conductor, and one electrode closer to another electrode, the gate electrode and the gate insulating layer of a vertical-structure transistor need to be designed to facilitate a catalyst reaction.

### SUMMARY OF THE INVENTION

An object of the present invention is to provide a small and high-performance sensor device employing a vertical bio-transistor that can operate at high speed.

According to one aspect of the present invention, a sensor device includes a porous insulating layer formed of a porous insulating material; a first electrode having a first opening portion and formed on a first side of the porous insulating layer; a second electrode having a second opening portion corresponding to the first opening portion and formed on a second side of the porous insulating layer; an insulating layer formed on the second electrode; and a molecular recognition material disposed on an internal wall of an opening in the porous insulating layer.

According to another aspect of the present invention, a sensor device includes a low-resistance substrate having a first opening portion; a first electrode formed on a first side of the low-resistance substrate; a porous insulating layer formed on a second side of the low-resistance substrate; a second electrode having a second opening portion corresponding to the first opening portion and formed on the porous insulating layer; an insulating layer formed on the second electrode; and a molecular recognition material disposed on an internal wall of an opening in the porous insulating layer.

According to another aspect of the present invention, there is provided a method of measuring characteristics of a solution or a substance contained in the solution, or an amount of the substance using a sensor device having a porous insulating layer formed of a porous insulating material; a first electrode having a first opening portion and formed on a first side of the porous insulating layer; a second electrode having a second opening portion corresponding to the first opening portion and formed on a second side of the porous insulating layer; an insulating layer formed on the second electrode; and a molecular recognition material disposed on an internal wall of an opening in the porous insulating layer.

The method includes immersing the first electrode, the second electrode, and the porous insulating layer of the sensor device in the solution; applying a voltage across the first electrode and the second electrode; and detecting an amount of an electric current that flows through the first and the second electrodes.

### BRIEF DESCRIPTION OF THE DRAWINGS

Other objects, features and advantages of the present invention will become apparent upon consideration of the specification and the appendant drawings, in which:

FIG. 1 depicts a schematic cross section and an electric circuit diagram of a conventional bio-transistor;

FIG. 2 illustrates the concept of a three-phase zone formed by an enzyme catalyst, an ion conductor, and fuel in an anode enzyme electrode reaction system according to an energy conversion technology;

FIG. 3 depicts a schematic cross section and an electric circuit diagram of a single element of a vertical bio-transistor according to Example 1 of the present invention;

FIG. 4 depicts a porous portion of the vertical bio-transistor of Example 1;

FIG. 5 illustrates an operating principle of a biosensor;

FIG. 6 depicts a schematic cross section and an electric circuit diagram of a single element of a vertical bio-transistor according to Example 2;

FIG. 7 depicts a schematic cross section and an electric circuit diagram of a single element of a vertical bio-transistor according to Example 3 of the present invention;

FIGS. 8A through 8I illustrate a process of manufacturing a vertical bio-transistor;

FIGS. 9A through 9E depicts perspective, transparent views illustrating fundamental steps of the process illustrated in FIG. 8; and

FIG. 10 depicts a schematic cross section and an electric circuit diagram of a single element of a vertical bio-transistor according to Example 4 of the present invention.

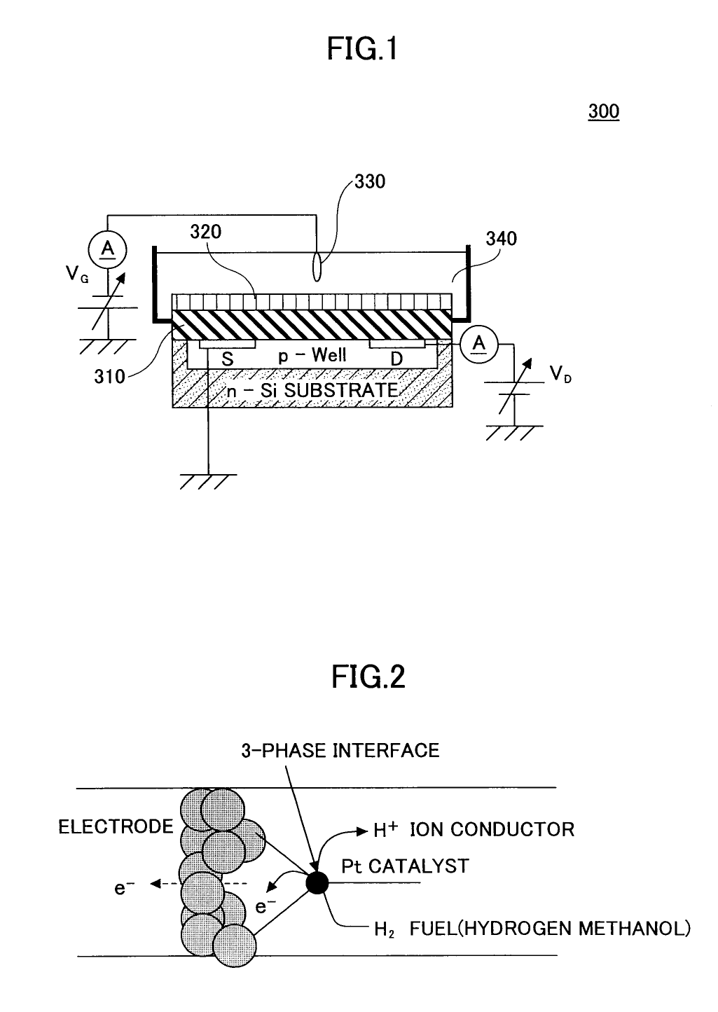

### DETAILED DESCRIPTION OF THE PREFERRED EMBODIMENTS

Referring now to the drawings, wherein like reference numerals designate identical or corresponding parts throughout the several views, a preferred embodiment of the present invention is described with reference to the drawings.

### <Vertical Bio-Transistor Single Element>

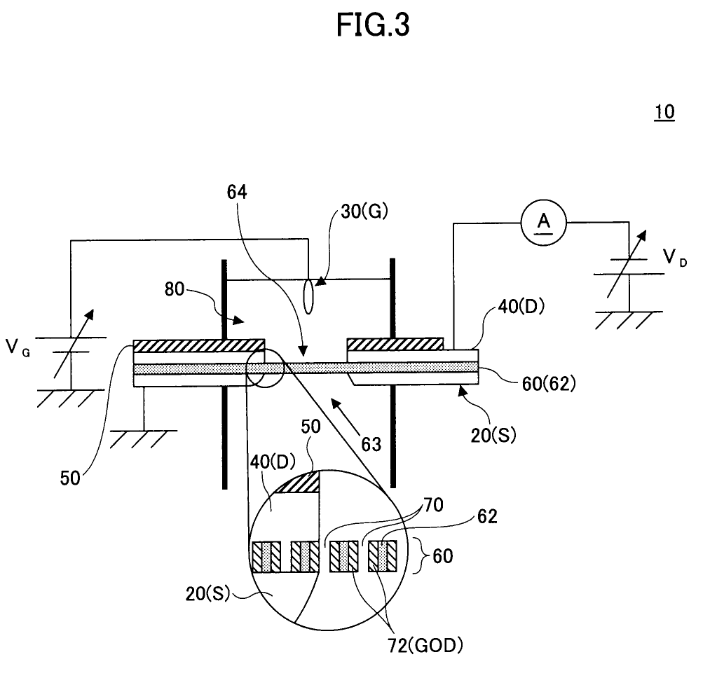

FIG. 3 depicts a schematic cross section and an electric circuit diagram of a single element of a vertical bio-transistor 10 according to an embodiment of the present invention. The vertical bio-transistor 10 includes a porous portion 60 on one side of which there is formed a source electrode 20 having a first opening portion 63. On the other side of the porous portion 60, there is formed a drain electrode 40 having a second opening portion 64. An insulating layer 50 is formed on the drain electrode 40, and a gate electrode 30 is disposed in midair away from the source electrode 20 and the drain electrode 40.

The circle of enlarged view within FIG. 3 depicts a cross section of the porous portion 60 which is formed by a porous alumina (porous Al₂O₃) 62. The porous portion 60 provides a porous insulating layer and has a number of openings 70 that penetrate the porous portion 60 vertically. The openings 70 allow communication between the one side on which the source electrode 20 is formed and the other side on which the drain electrode 40 is formed. On the inner walls of the openings 70, there is an immobilized enzyme, such as glucose oxidase (GOD) 72 which is a glucose degrading enzyme. The openings 70 having the GOD 72 immobilized thereon provide spatial gaps vertically penetrating the porous portion 60.

The first and second opening portions 63 and 64 provide openings via which the porous alumina 62 of the porous portion 60 can be exposed to the atmosphere. The first and second opening portions 63 and 64 may have a corresponding shape, such as a rectangular, a circular, or an elliptical shape. The source electrode 20 may be made of an electrically conductive material such as aluminum (Al), providing a first electrode. The drain electrode 40 provides a second electrode. The gate electrode 30, which is disposed in midair above the drain electrode 40, provides a third electrode (reference electrode (Pt black)). In this structure, when the source electrode 20 emits carriers that are received by the drain electrode 40, resistance to charge conduction in the source electrode 20 can be reduced so that a current can flow efficiently between the source electrode 20 and the drain electrode 40.

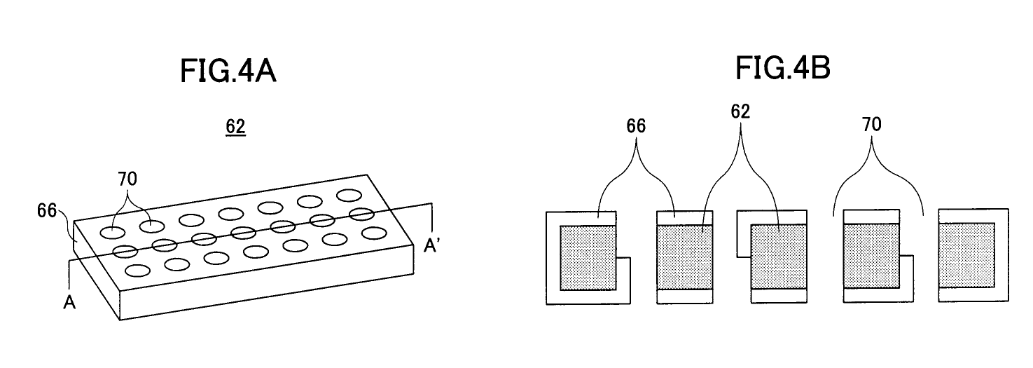

FIG. 4A illustrates a schematic perspective view of the porous portion 60. FIG. 4B illustrates a cross section taken along line A-A′ of FIG. 4A. The entire surfaces of the porous portion 60 may be covered with a layer of the same metal material as that of the drain electrode 40, such as an aluminum layer 66. Thus, the porous portion 60 has the same potential as that of the drain electrode 40. Preferably, the aluminum layer 66 also covers a part of the internal walls of the openings 70, as illustrated in FIG. 4B.

### Example 1

In Example 1, the vertical bio-transistor 10 depicted in FIG. 3 is immersed in a solution 80, such as a solution of blood, to detect a current that flows between the source electrode 20 and the drain electrode 40. The property or amount of the solution or a material contained in it is determined based on the detected current value.

The GOD 72, which is a glucose oxidoreductase, oxidizes glucose in accordance with the following expression (1), producing hydrogen peroxide (H₂O₂):

C₆H₁₂O₆+O₂→C₆H₁₀O₆+H₂O₂ (1)

Hemoglobin in blood in the case of a blood solution is oxidized by the GOD 72 whereby the ion concentration of the solution changes. Thus, by controlling the increase or decrease in potential by controlling a bias voltage VD_{S} and a gate voltage V_{G}, the amount of the carrier that travels from the source electrode 20 to the drain electrode 40 changes. Thus, by detecting a change in the threshold voltage of the transistor or a change in its current value for the same potential due to the change in charge density as a result of oxidoreduction, the vertical bio-transistor 10 can be used as a biosensor.

Because the carriers that move from the source electrode 20 to the drain electrode 40 travel through the spatial gaps of the openings 70 in the first opening portion 63 and the second opening portion 64 of the porous portion 60, the resistance to charge transfer can be reduced. The carriers move through the effective spatial gaps of the openings 70 in the porous portion 60 with a controlled depletion layer, in accordance with a voltage applied between the source electrode 20 and the drain electrode 40. Thus, by detecting a change in the threshold voltage of the vertical bio-transistor 10 and a change in its drain current, and determining a standard curve for the change in ion concentration, the vertical bio-transistor 10 can be used as a sensor for diagnosing diabetes, for example, based on the detected amount of glucose.

The drain electrode 40 may be formed in various shapes. Preferably, the drain electrode 40 includes a voltage-applied portion of electrically conductive material to which a gate voltage is applied, where a current path in the porous portion 60 is formed adjacent the voltage-applied portion of the drain electrode 40.

As described above, the vertical bio-transistor 10 can be used as a glucose sensor for detecting a change in charge amount due to the production of water (H₂O) and oxygen ion (O⁻) accompanying the production of H₂O₂ as a result of the redox reaction of glucose by the glucose oxidase (GOD). The same above sensor structure may also be used as a complex adsorption sensor utilizing physical adsorption, chemical adsorption, and a combination of physical adsorption and chemical adsorption, as described in detail below.

### <Principle of Biosensor>

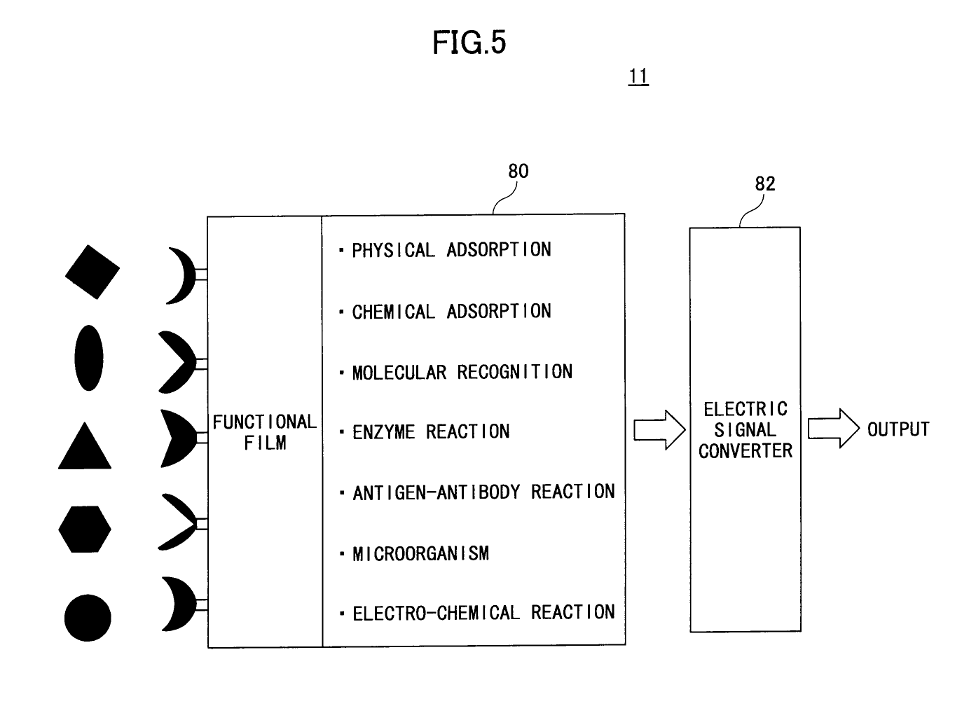

With reference to FIG. 5, the principle of a biosensor is described. As shown in FIG. 5, a biosensor 11 includes a functional membrane 80. A change due to various reactions in or on the functional membrane 80 is converted by an electric signal convertor 82 into an electric signal that is detected. The reactions in or on the functional membrane 80 may include reactions involving physical adsorption, chemical adsorption, or molecular adsorption; an enzyme response, an antigen-antibody reaction, a reaction involving a microorganism, an electrochemical reaction, and a reaction involving DNA. The reactions may involve any other combinations of the functional membrane 80 and a substance or matter that cause a potential change or exhibit selectivity.

### Example 2

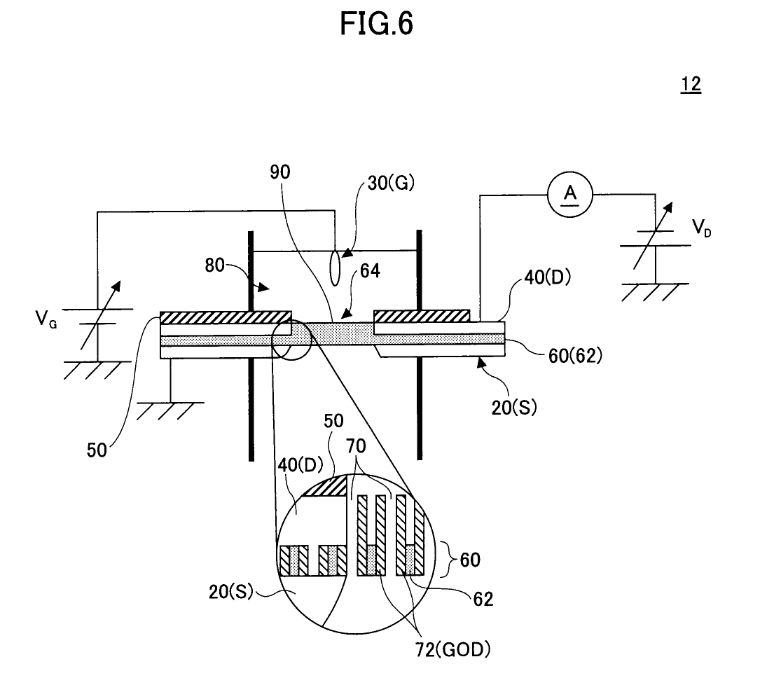

FIG. 6 depicts a schematic cross section and an electric circuit diagram of a single element of a vertical bio-transistor 12 according to Example 2 of the present invention. The vertical bio-transistor 12 is similar to the vertical bio-transistor 10 according to Example 1 with the exception that the porous portion 60 has a portion 90 in the second opening portion 64 that is extended toward the gate electrode 30. Specifically, in the second opening 64, the GOD 72 extends toward the gate electrode 30 with respect to the porous alumina 62. A channel portion as a current path of the transistor adjacent the drain electrode 40 has a length corresponding to the film thickness of the drain electrode 40.

Thus, the carriers that travel through the spatial gaps of the openings 70 formed in the porous portion 60 can travel more efficiently than in Example 1 through the effective spatial gaps with a controlled depletion layer, the spatial gaps being changed by the voltage applied to the drain electrode 40. Thus, in this structure, the sensitivity of the vertical bio-transistor 12 is enhanced by the decrease in operating resistance, thereby achieving higher operating speed and faster response. The vertical bio-transistor 12 can also function as a highly accurate sensor because of the increase in current density.

The porous portion 60 and the insulating layer 50 may include a metal oxide selected from the group (a) consisting of zinc oxide, titanium oxide, tin oxide, indium oxide, aluminum oxide, niobium oxide, tantalum pentoxide, barium titanate, and strontium titanate. Alternatively, the metal oxide may be selected from the group (b) consisting of nickel oxide, cobalt oxide, iron oxide, manganese oxide, chromium oxide, and bismuth oxide. Alternatively, the metal oxide may be formed by doping an impurity into one of the metal oxides selected from the group (a) or (b).

The material of the porous portion 60 may include anodized alumina (Al₂O₃) or zinc oxide (ZnO). Anodization performed under certain conditions enables the formation of a number of uniform pores, thereby achieving a high carrier mobility and realizing a highly sensitive vertical bio-transistor.

The molecular recognition material may include one or the other of paired substances in any of the following combinations: (1) an enzyme, which is a substance that catalyzes a chemical reaction that occurs in a living body, such as glucose oxidase, diastase, pepsine, trypsin, papain, bromelain, thrombin, lipase, lipoprotein lipase, monooxygenase, peroxidase, ATP synthase, DNA polymerase, RNA polymerase, nuclease, aminoacyl tRNA synthetase, kinase, phosphatase, glycosyltransferase, or DNA methylase, and its substrate; (2) any of the enzymes in (1) and a coenzyme, such as NAD, NADP, FMN, FAD, thiamin diphosphate, pyridoxal-phosphate, coenzyme A, ribonucleic acid, or folic acid; (3) an antigen, such as Escherichia coli, Bacillus subtilis including Bacillus natto, bacterium including cyanobacterium, virus, or a protein that enters a living body, such as a pathogen, and an antibody that exhibits effective reactivity against such an antigen, such as a glycoprotein molecule produced by T cell, B cell, or NK cell, which are examples of lymphocyte; and (4) a hormone, such as inhibin, parathormone, calcitonin, thyroid stimulation hormone, melatonin, insulin, glucagon, and growth hormone, and its receptor. One of the paired substances in any of the above combinations (1) through (4), such as an enzyme, is immobilized on the internal walls of the openings in the porous alumina 62 as the molecular recognition material, to selectively measure the other substance in the pair, such as a coenzyme.

### Example 3

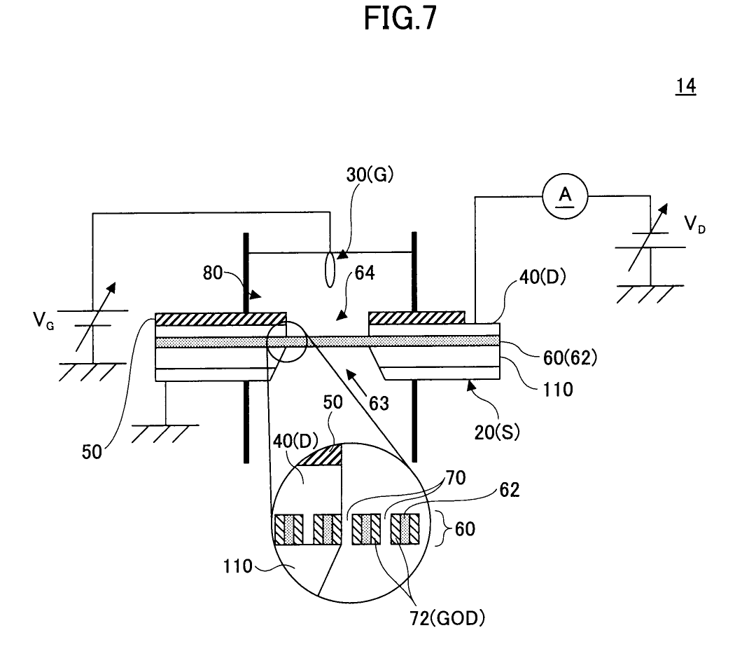

FIG. 7 depicts a schematic cross section and an electric circuit diagram of a single element of a vertical bio-transistor 14 according to Example 3. The vertical bio-transistor 14 includes a silicon (Si) substrate 110 as a low-resistance member which is disposed between the source electrode 20 and the porous portion 60. The vertical bio-transistor 10 depicted in FIG. 3 may be disposed on the substrate 110 that is formed in concave shape.

### <Process of Manufacturing a Vertical Bio-Transistor>

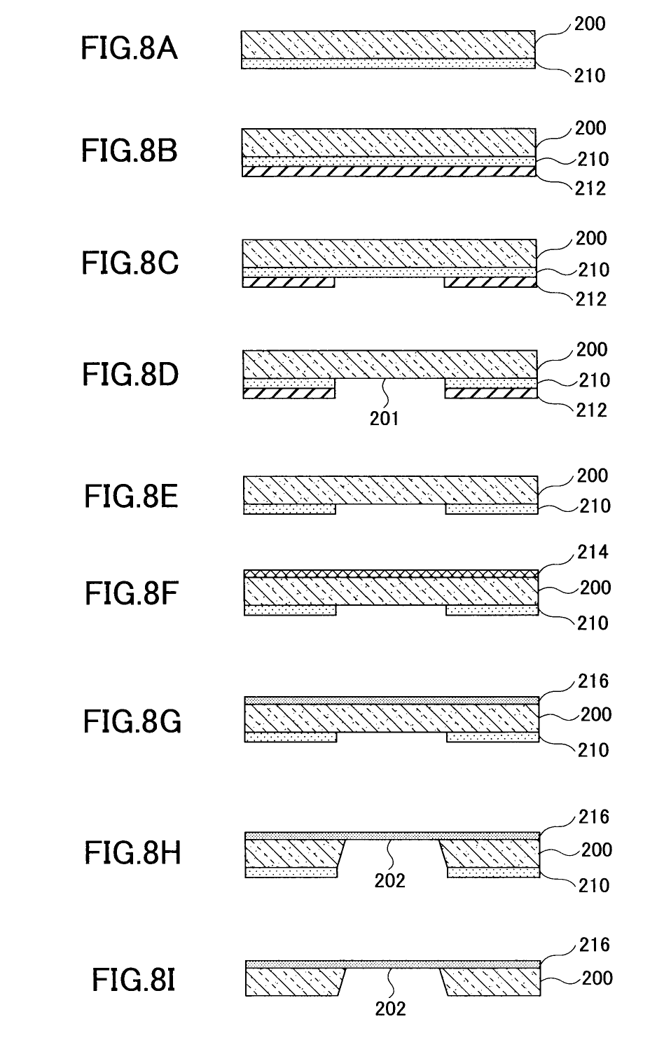

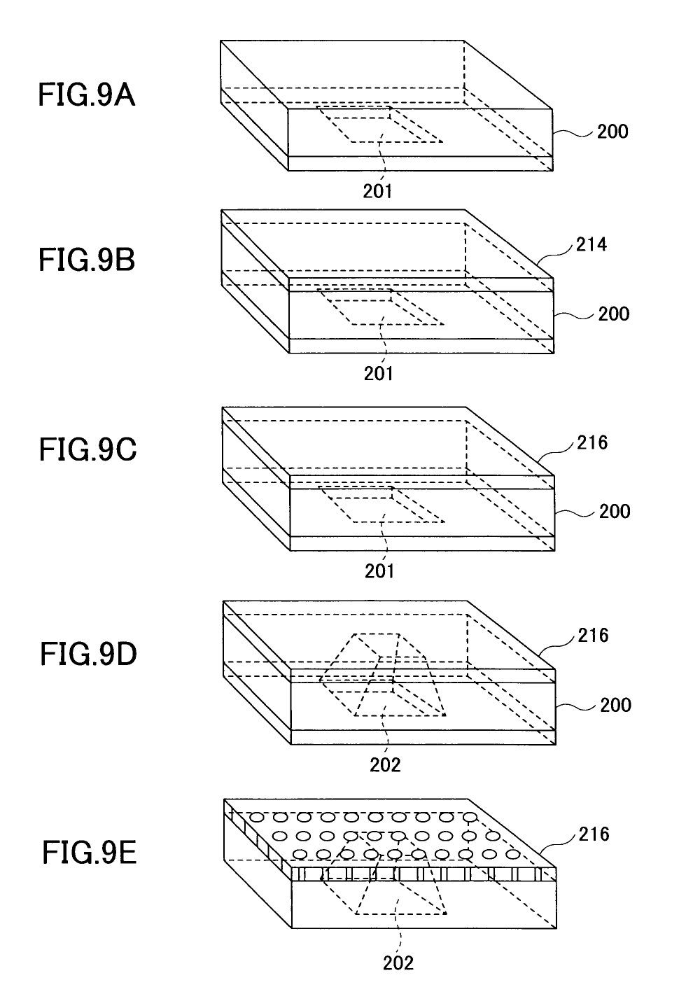

With reference to FIGS. 8 and 9, a process of manufacturing the vertical bio-transistor 14 depicted in FIG. 7 is described. FIGS. 8A through 8I illustrate the steps of the process of manufacturing the vertical bio-transistor. FIGS. 9A through 9E depict perspective transparent views illustrating fundamental steps of the process illustrated in FIG. 8.

In FIG. 8A, an oxide layer is formed on a lower surface of a substrate by thermal oxidation. Specifically, a layer of silicon (Si) oxide 210 having a thickness of about 1 μm is formed on a lower surface of a low-resistance silicon (Si) substrate 200 having a thickness of about 200 μm and plane orientation (001) by thermal oxidation.

In FIG. 8B, a resist 212 is applied to a lower surface of the silicon oxide layer 210 by the spin coat method to a film thickness of about 300 nm.

In FIG. 8C, the resist 212 is exposed and developed, thereby forming a pattern of the resist 212.

In FIG. 8D, the substrate 200 is immersed in a hydrofluoric acid (HF) solution diluted with water, in order to remove the silicon oxide 210 in an area in which the resist pattern is not formed. In this way, a window opening 201 is formed which may be rectangular, circular, or elliptical.

In FIGS. 8E and 9A, the resist 212 is removed with a solvent or by dry ashing or the like.

In FIGS. 8F and 9B, an aluminum film 214 is formed on the silicon substrate 200 at room temperature by the vacuum evaporation method at the vacuum condition of about 1.3 to about 3.9×10⁻³ Pa to a film thickness of about 100 nm and preferably about 10 nm.

In FIGS. 8G and 9C, the aluminum film 214 is anodized with a phosphoric acid aqueous solution at about 30° C. and a current density of about 3 to 7 mA/cm², thereby forming a layer of porous alumina 216. The layer of porous alumina 216 may be controlled to have a pore diameter of about 5 to 450 nm and a pore pitch of about 10 to 500 nm.

In FIGS. 8H and 9D, a central portion 202 of the silicon substrate 200 is removed using a potassium hydroxide (KOH) solution diluted with water, forming a so-called “forward” mesa of about 54.7°. Thus, the first opening portion 63 depicted in FIG. 7 is formed.

In FIGS. 8I and 9E, the silicon substrate 200 is immersed in a hydrofluoric acid (HF) solution diluted with water to remove the silicon oxide 210.

Thereafter, glucose oxidase (GOD) is immobilized on the internal walls of the porous alumina 216, and the source electrode 20 having the first opening portion 63 is formed on the silicon substrate 200. Further, the drain electrode 40 having the second opening portion 64 corresponding to the first opening portion 63 is formed of an aluminum electrode having a thickness of about 100 nm by vacuum deposition. After providing a metal mask, the insulating film 50 is formed by sputtering silicon oxide (SiO₂).

In this way, the vertical bio-transistor 14 according to Example 3 is manufactured. The silicon substrate 200 depicted in FIGS. 8 and 9 corresponds to the silicon substrate 110 depicted in FIG. 7, and the porous alumina 216 depicted in FIGS. 8 and 9 corresponds to the porous alumina 62 depicted in FIG. 7.

### Example 4

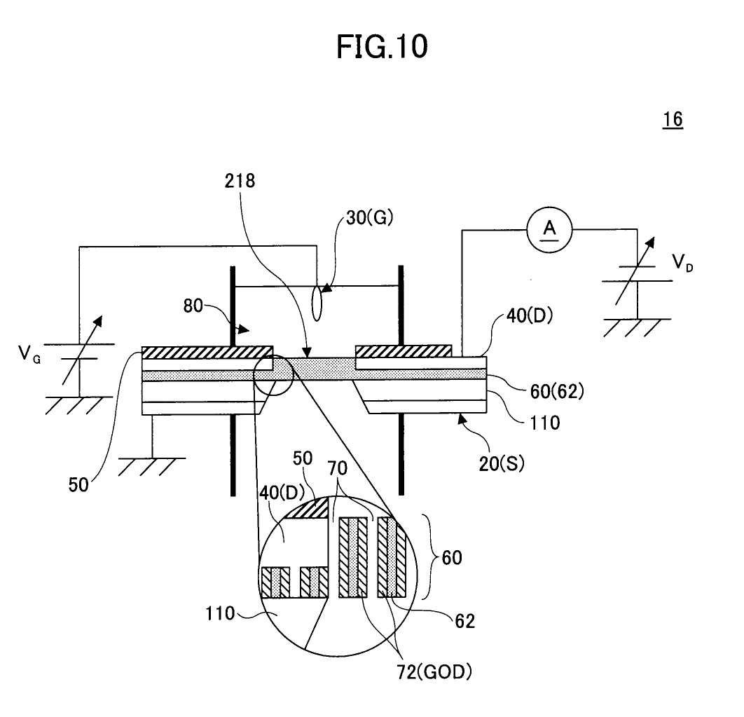

FIG. 10 depicts a schematic cross section and an electric circuit diagram of a single element of a vertical bio-transistor 16 according to Example 4. The bio-transistor 16 may be manufactured by extending the porous alumina 216 in a second opening portion 218 in the steps depicted in FIGS. 8G through 8H toward the gate electrode 30.

More specifically, glucose oxidase (GOD) 72 is immobilized on the internal walls of the openings 70 in the porous portion 60 of the vertical bio-transistor 16 in the second opening portion 218 facing the gate electrode 30 to the same height as the surface of the porous alumina 62. Compared to the vertical bio-transistor 14 depicted in FIG. 7, the vertical bio-transistor 16 can exhibit an improved charge generation efficiency with respect to a voltage applied to the drain electrode 40 and an increase in source-drain current.

### Example 5

In Example 5, the porous alumina 62 of the vertical bio-transistor 14 depicted in FIG. 7 is replaced with a film of zinc oxide. In Example 5, too, similar sensor operation to the foregoing examples can be achieved.

### Example 6

In Example 6, the porous alumina 62 of the vertical bio-transistor 14 depicted in FIG. 7 is replaced with a chromium oxide film. In this case, too, similar sensor operation to the foregoing examples can be achieved.

### Example 7

In Example 7, the drain electrode 40 of the vertical bio-transistor 14 depicted in FIG. 7 is formed using Au instead of aluminum. In this case, too, similar sensor operation to the foregoing examples can be achieved.

### Example 8

In Example 8, the drain electrode 40 of the vertical bio-transistor 14 depicted in FIG. 7 is formed using Pd instead of Al. In this case, too, similar sensor operation to the foregoing examples can be achieved.

### Example 9

In Example 9, the drain electrode 40 of the vertical bio-transistor 14 depicted in FIG. 7 is formed using an electrically conductive metal oxide, specifically zinc oxide doped with Al, instead of Al. In this case too, similar sensor operation to the foregoing examples can be achieved.

### Example 10

In Example 10, the drain electrode 40 of the vertical bio-transistor 14 depicted in FIG. 7 is formed using electrically conductive polyaniline, instead of Al. In this case, too, similar sensor operation to that of the foregoing examples can be achieved.

When the I-V characteristics of the vertical bio-transistors according to Examples 1 through 10 were measured, substantially the same measurement results were obtained, indicating that the vertical bio-transistors according to Examples 1 through 10 can provide similar effects.

### Example 11

The metal oxide in the aforementioned insulating layer may include a material selected from the group consisting of silicon oxide, tantalum oxide, titanium oxide, aluminum oxide, hafnium oxide, zircon oxide, lanthanum oxide, scandium oxide, praseodymium oxide, bismuth oxide, niobium oxide, tungsten oxide, yttrium oxide, and silicon nitride.

Thus, in accordance with an embodiment of the present invention, a high-performance sensor device having a novel structure and exhibiting sensor characteristics unique to a vertical bio-transistor can be provided. Further, an embodiment of the present invention provides a sensor device and a circuit structure using a vertical transistor that exhibit a high carrier mobility and a steep rise signal in output current (source-drain current), thus enabling a high operating speed. Another embodiment of the present invention provides a method of measuring a solution using the sensor device according to an embodiment of the present invention.

Although this invention has been described in detail with reference to certain embodiments, variations and modifications exist within the scope and spirit of the invention as described and defined in the following claims.

The present application is based on the Japanese Priority Applications No. 2008-298827 filed Nov. 21, 2008 and No. 2008-328408 filed Dec. 24, 2008, the entire contents of which are hereby incorporated by reference.

What is claimed is:

1. A sensor device comprising:
a porous insulating layer formed of a porous insulating material;
a first electrode having a first opening portion and formed on a first side of the porous insulating layer;
a second electrode having a second opening portion corresponding to the first opening portion and formed on a second side of the porous insulating layer;
an insulating layer formed on the second electrode; and
a molecular recognition material disposed on an internal wall of an opening in the porous insulating layer.

2. A sensor device comprising:
a low-resistance substrate having a first opening portion;
a first electrode formed on a first side of the low-resistance substrate;
a porous insulating layer formed on a second side of the low-resistance substrate;
a second electrode having a second opening portion corresponding to the first opening portion and formed on the porous insulating layer;
an insulating layer formed on the second electrode; and
a molecular recognition material disposed on an internal wall of an opening in the porous insulating layer.

3. The sensor device according to claim 1, further comprising a third electrode disposed away from the first electrode and the second electrode.

4. The sensor device according to claim 1, wherein the porous insulating layer includes a plurality of the openings that allow communication between the first side and the second side of the porous insulating layer.

5. The sensor device according to claim 1, wherein the molecular recognition material produces a redox reaction with a solution or a substance contained in the solution.

6. The sensor device according to claim 3, wherein the porous insulating layer protrudes toward the third electrode in the first opening portion or the second opening portion.

7. The sensor device according to claim 3, wherein the molecular recognition material protrudes toward the third electrode in the first opening portion or the second opening portion with respect to the porous insulating layer.

8. The sensor device according to claim 1, wherein the porous insulating layer includes at least one metal oxide either selected from a group (a) consisting of zinc oxide, titanium oxide, tin oxide, indium oxide, aluminum oxide, niobium oxide, tantalum pentoxide, barium titanate, and strontium titanate; or a group (b) consisting of nickel oxide, cobalt oxide, iron oxide, manganese oxide, chromium oxide, and bismuth oxide; or made by doping an impurity into at least one metal oxide selected from the group (a) or (b).

9. The sensor device according to claim 1, wherein the molecular recognition material includes one or the other of paired substances in any of the following combinations: (1) an enzyme and its substrate; (2) an enzyme and a coenzyme; (3) an antigen and an antibody having an effective reactivity to the antigen; and (4) a hormone and a receptor,
wherein the molecular recognition material is configured to selectively measure one or the other substance in each of the combinations (1) through (4),
wherein the enzyme in the combination (1) includes at least one enzyme selected from a group consisting of glucose oxidase, diastase, pepsine, trypsin, papain, bromelain, thrombin, lipase, lipoprotein lipase, monooxygenase, peroxidase, ATP synthase, DNA polymerase, RNA polymerase, nuclease, aminoacyl tRNA synthetase, kinase, phosphatase, glycosyltransferase, and DNA methylase,
the coenzyme in the combination (2) includes at least one coenzyme selected from a group consisting of NAD, NADP, FMN, FAD, thiamin diphosphate, pyridoxal-phosphate, coenzyme A, ribonucleic acid, and folic acid,
the antigen in the combination (3) includes at least one antigen selected from a group consisting of Escherichia coli, Bacillus natto, cyanobacterium, virus, and a pathogen,
the antibody in the combination (3) includes at least one antibody selected from a group consisting of glycoprotein molecules produced by T cell, B cell, or NK cell, and
the hormone in the combination (4) includes at least one hormone selected from a group consisting of inhibin, parathormone, calcitonin, thyroid stimulation hormone, melatonin, insulin, glucagon, and growth hormone.

10. The sensor device according to claim 3, wherein the first electrode, the second electrode, or the third electrode includes at least one material selected from a group consisting of chromium, thallium, titanium, copper, aluminum, molybdenum, tungsten, nickel, gold, palladium, platinum, silver, tin, lithium, calcium, indium tin oxide, electrically conductive metal oxide of zinc oxide, electrically conductive polyaniline, electrically conductive polypyrrole, electrically conductive polythiazyl, and electrically conductive polymer.

11. A method of measuring characteristics of a solution or a substance contained in the solution, or an amount of the substance using a sensor device having a porous insulating layer formed of a porous insulating material; a first electrode having a first opening portion and formed on a first side of the porous insulating layer; a second electrode having a second opening portion corresponding to the first opening portion and formed on a second side of the porous insulating layer; an insulating layer formed on the second electrode; and a molecular recognition material disposed on an internal wall of an opening in the porous insulating layer,
the method comprising:
immersing the first electrode, the second electrode, and the porous insulating layer of the sensor device in the solution;
applying a voltage across the first electrode and the second electrode; and
detecting an amount of an electric current that flows through the first and the second electrodes.

12. The method according to claim 11, wherein the sensor device further includes a third electrode disposed away from the first and the second electrodes,
the method further comprising applying a certain voltage to the third electrode.
